(19) United States
(12) Patent Application Publication
(10) Pub. No.: US 2006/0246811 A1
(43) Pub. Date: Nov. 2, 2006

(54) Encapsulating emissive portions of an OLED device

(75) Inventors: Dustin L. Winters, Webster, NY (US); Amalkumar P. Ghosh, Fishkill, NY (US); Michael L. Boroson, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/116,743

(22) Filed: Apr. 28, 2005

(51) Int. Cl. H05B 33/10; H05B 33/04

(52) U.S. Cl. 445/25; 313/512

(57) ABSTRACT

A method of providing an encapsulation layer over an emissive portion of an OLED device includes providing an OLED substrate having one or more OLED devices, each device having an emissive portion and a connector portion, positioning the OLED substrate in sealing engagement with at least one opening in a deposition chamber to define a deposition environment for the emissive portion(s) and a non-deposition environment for the connector portion(s), and depositing in the deposition environment an encapsulation layer onto the emissive portion of the OLED device through the opening without depositing the encapsulation layer over the connector portion.

### FIELD OF THE INVENTION

The present invention relates to manufacture of OLED devices. More specifically, it relates to protection of the OLED device by selective encapsulation.

### BACKGROUND OF THE INVENTION

An organic light-emitting diode device, also called an OLED device, commonly includes organic electroluminescent media disposed between first and second electrodes. The first and second electrodes serve as an anode for hole injection and a cathode for electron injection. The organic electroluminescent media supports recombination of holes and electrons that yields emission of light. OLED devices are attractive because of their low driving voltage, high luminance, wide-angle viewing and capability for full color flat emission displays. Tang et al. describes this multilayer OLED device in their U.S. Pat. Nos. 4,769,292 and 4,885,211.

A common problem with OLED displays is sensitivity to water. If water molecules reach or penetrate an OLED device, the operational lifetime of the device can be reduced significantly. One approach to maintaining acceptable humidity levels within a packaged device is to encapsulate or seal the device along with a desiccant within a cover. Desiccants such as, for example, barium oxide and calcium oxide, are used to reduce the humidity level.

Another approach to providing moisture protection of OLED devices has been described in U.S. Patent Application Publications 2001/0052752 A1 and 2002/0003403 A1. In this approach, an encapsulation assembly is disposed over the OLED devices and over at least a portion of the substrate. The encapsulation assembly includes an oxide layer, such as aluminum oxide, which is directly in contact with at least a portion of the rigid substrate. This layer is deposited by a highly conformal method such as atomic layer deposition (ALD) to provide a pinhole-free moisture seal. This method thereby provides moisture protection by way of a thin film coating, which is integral with an OLED device and, accordingly, does not require device sealing within or by a separate enclosure. This thereby reduces size and weight, as well as cost of the encapsulation means.

However, films deposited by ALD methods, as suggested in by U.S. Patent Application Publications 2001/0052752 A1 and 2002/0003403 A1, coat the entire substrate, thereby covering all features on the substrate including any connector pad features for making electrical connections to the device. Therefore, the encapsulation film needs to be subsequently removed in these selective regions to permit for electrical connections to be made to the OLED device, thereby necessitating additional steps in the manufacturing process.

### SUMMARY OF THE INVENTION

It is therefore an object of the present invention to selectively deposit a protective layer over a portion of an OLED device while not depositing the layer over another area of an OLED device in a manner that does not add other manufacturing steps.

This object is achieved by a method of providing an encapsulation layer over an emissive portion of an OLED device comprising:

a) providing an OLED substrate having one or more OLED devices, each device having an emissive portion and a connector portion;

b) positioning the OLED substrate in sealing engagement with at least one opening in a deposition chamber to define a deposition environment for the emissive portion(s) and a non-deposition environment for the connector portion(s); and

c) depositing in the deposition environment an encapsulation layer onto the emissive portion of the OLED device through the opening without depositing the encapsulation layer over the connector portion.

### Advantages

It is an advantage of this method that it provides an OLED device having an integral encapsulation film which is low weight and low cost, where the encapsulation film is selectively deposited only over desired areas of the substrate so as to reduce manufacturing steps.

### BRIEF DESCRIPTION OF THE DRAWINGS

FIG. 1 shows a three-dimensional view of an OLED substrate having several OLED devices, which can be encapsulated by the method of the present invention;

FIG. 2 shows a plan view of one of the above OLED devices, showing an emissive portion and a connector portion;

FIG. 3 shows a three-dimensional view of one embodiment of an apparatus that can be used in the method of the present invention to encapsulate the emissive portion of one or more OLED devices;

FIG. 4 shows a schematic cross-sectional view of one embodiment of an OLED device that has been encapsulated by the method of the present invention;

FIG. 5 shows a three-dimensional view of another embodiment of an apparatus that can be used in the method of the present invention to encapsulate the emissive portion of one or more OLED devices;

FIG. 6A shows a schematic cross-sectional view of another embodiment of an apparatus that can be used to encapsulate the emissive portion of one or more OLED devices;

FIG. 6B shows a top view of the OLED device in FIG. 6A;

FIG. 6C shows the formation of deposition and non-deposition environments on the OLED device of FIG. 6B;

FIG. 7 shows a schematic representation of a manufacturing tool for producing OLED devices according to an embodiment of the present invention; and

FIG. 8 shows a block diagram of one embodiment of the method of the present invention.

Since device feature dimensions such as layer thicknesses are frequently in sub-micrometer ranges, the drawings are scaled for ease of visualization rather than dimensional accuracy.

### DETAILED DESCRIPTION OF THE INVENTION

The term “OLED device” or “organic light-emitting diode device” is used in its art recognized meaning of a display device comprising organic light-emitting diodes as pixels. A color OLED device emits light of at least one color. The term “multicolor” is employed to describe a display panel that is capable of emitting light of a different hue in different areas. In particular, it is employed to describe a display panel that is capable of displaying images of different colors. These areas are not necessarily contiguous. The term “full color” is commonly employed to describe multicolor display panels that are capable of emitting in at least the red, green, and blue regions of the visible spectrum and displaying images in any combination of hues. The red, green, and blue colors constitute the three primary colors from which all other colors can be produced by appropriate mixing. However, the use of additional colors to extend the color gamut of the device is possible. The term “hue” refers to the intensity profile of light emission within the visible spectrum, with different hues exhibiting visually discernible differences in color. The term “pixel” is employed in its art recognized usage to designate an area of a display panel that can be stimulated to emit light independently of other areas. It is recognized that in full color systems, several pixels of different colors will be used together to produce a wide range of colors, and a viewer can term such a group a single pixel. For the purposes of this discussion, such a group will be considered several different colored pixels.

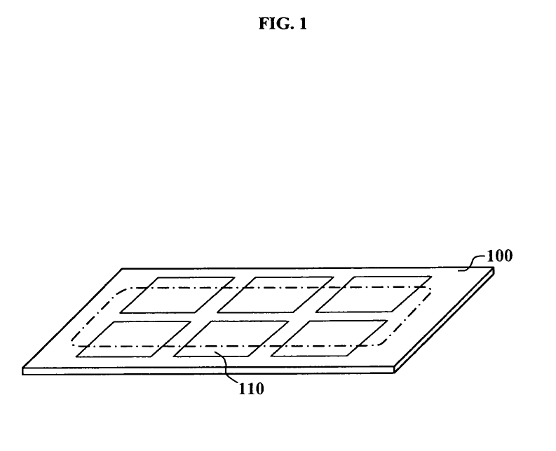

Turning now to FIG. 1, there is shown a perspective of an OLED substrate having several OLED devices, which can be encapsulated by the method of the present invention. For the purposes of the present invention, the term “encapsulated” means that an OLED device possesses a protective layer or encapsulation layer over the top. In certain cases, such as protection against moisture or oxygen, it is desirable that the encapsulation layer also seals the sides of the various OLED layers, thus completely enclosing at least a portion of the OLED device. When it is desired to have protection against abrasion by physical means or by limited chemical contact, it is often sufficient that the encapsulation layer cover only the top of the OLED device to consider that the device is encapsulated. OLED substrate 100, which is also called a display substrate, can have one or a plurality of OLED devices 110, which are also called display devices. OLED substrate 100 can be an organic solid, an inorganic solid, or includes organic and inorganic solids, and can be a homogeneous mixture of materials, a composite of materials, or multiple layers of materials. OLED substrate 100 can be rigid or flexible and can be processed as separate individual pieces, such as sheets or wafers, or as a continuous roll. Typical substrate materials include glass, plastic, metal, ceramic, semiconductor, metal oxide, semiconductor oxide, or semiconductor nitride, or combinations thereof, active-matrix low-temperature polysilicon, or an amorphous-silicon TFT substrate.

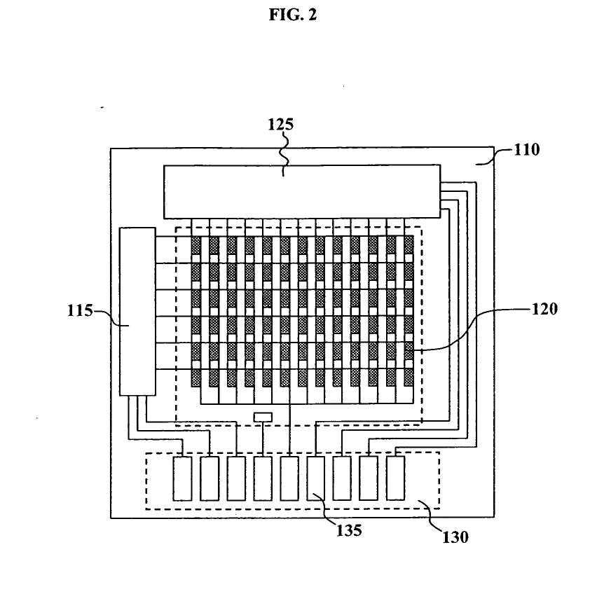

Turning now to FIG. 2, there is shown a plan view of one of the above OLED devices of FIG. 1. OLED device 110 includes an emissive portion 120, which is also called an active portion, and a connector portion 130. Emissive portion 120 includes an anode, a series of anodes, or an array of anodes; a cathode, a series of cathodes, or an array of cathodes; and one or more emissive OLED elements or pixels, which will be further described below. In an OLED device, emissive portion 120 generally requires protection from the external environment, and especially from moisture and oxygen, for example by encapsulation. Connector portion 130 includes a series of conductive contacts, such as connector pad 135, that provide a location for the input of external electrical power or luminance information in the form of the voltage or current signals. In order for these connector pads to make electrical connection to such external electrical sources, at least a portion of the connector pads should remain free of the encapsulation layer. Although connector portion 130 commonly is along one side of OLED device 110, it can occupy more than one side or even areas other than the side of OLED device 110. OLED device 110 can also include other areas, such a logic-decoding areas including row drivers 115 and column drivers 125. The other areas can be covered with a protective layer or not, as required by the particular device.

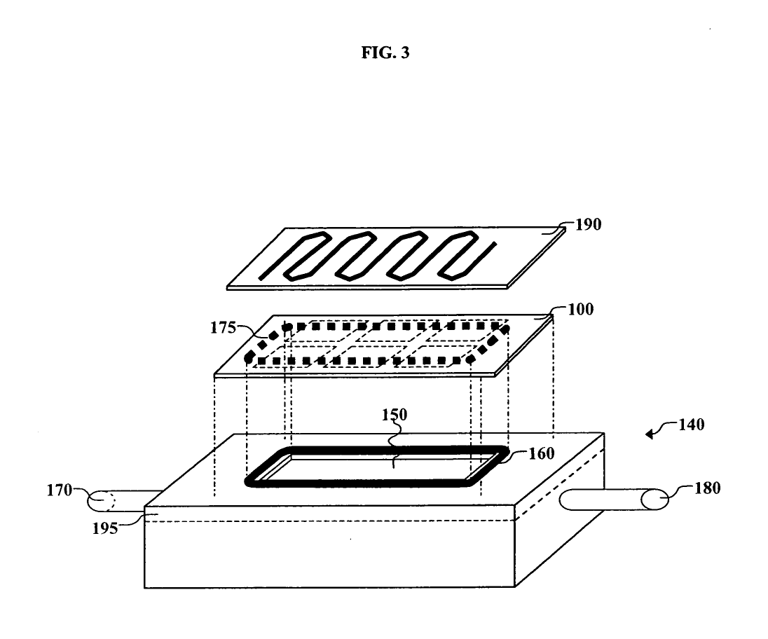

Turning now to FIG. 3, there is shown a three-dimensional view of one embodiment of an apparatus that can be used in the method of the present invention to encapsulate the emissive portion of one or more OLED devices. Deposition chamber 140 is used to deposit an encapsulation layer onto the emissive portion of one or more OLED devices. Deposition chamber 140 includes at least one opening 150 that will define a deposition environment for the emissive portion of the OLED device(s). OLED substrate 100 is positioned against opening 150 in such a way that the emissive portion(s) of the OLED device(s) on OLED substrate 100 will be exposed to the interior of deposition chamber 140. Sealing material 160 provides a sealing engagement 175 between OLED substrate 100 and deposition chamber 140 at opening 150. By sealing engagement, it is meant that OLED substrate 100, deposition chamber 140, and sealing material 160 form an airtight seal to define two environments independent of each other: a deposition environment for the emissive portion(s) of OLED substrate 100, and a non-deposition environment for the connector portion(s) of OLED substrate 100. The deposition environment includes the interior of deposition chamber 140. The non-deposition environment includes the exterior of deposition chamber 140 and can be provided by ambient conditions or by a larger chamber (not shown) that encloses at least the opening 150 of deposition chamber 140, OLED substrate 100, and any other necessary apparatus, such as positioning apparatus and heater 190. When the non-deposition environment is enclosed in a larger chamber, an inert gas such as nitrogen or argon can be provided in the non-deposition environment, preferably maintained at a pressure less than atmospheric pressure and greater than the pressure maintained in deposition chamber 140.

Sealing material 160 is preferably a material that can provide a seal when deformed under pressure, e.g. neoprene, rubber, or silicone. Sealing material 160 can be on deposition chamber 140, or on OLED substrate 100, or both. One example of a useful sealing material is a neoprene O-ring.

Deposition chamber 140 is useful for depositing in the deposition environment an encapsulation layer onto the emissive portion(s) of OLED substrate 100 by e.g. atomic layer deposition (ALD) without depositing the encapsulation layer over the connector portion(s) of OLED substrate 100. Deposition chamber 140 includes gas inlet 170 for introducing ALD-depositing gases, and outlet 180 for removing excess gasses and for maintaining low pressure inside deposition chamber 140. Gas inlet 170 can provide a source for multiple gases. For example, in order to form a film of aluminum oxide (Al₂O₃), gas inlet 170 can supply repeated pulses of trimethyl aluminum (TMA) followed by pulses of ozone (O₃). Gas inlet 170 can optionally provide flow of an inert gas such as argon or nitrogen between pulses of the different reactive gases in order to purge the chamber. Gas inlet 170 can be a single orifice or multiple orifices. Other gas injection arrangements such as a showerhead type apparatus with a nozzle array, as described by Sneh in U.S. Patent Application Publication 2003/0180458 A1 can also be used with the present invention.

In general, the deposition environment inside deposition chamber 140 will be at a lower pressure than the non-deposition environment external to the chamber. The apparatus can also include heater 190 for heating OLED substrate 100 so as to cause the formation of an encapsulation layer on OLED substrate 100 when it is exposed to ALD-depositing gases. Heater 190 is capable of maintaining the OLED substrate 100 at least at the process temperature of the ALD reaction. Reaction temperatures are preferably in the range of 100 to 120 degrees Celsius or lower to avoid damaging the electroluminescent materials.

Deposition chamber 140 can have a single-unit construction dedicated to encapsulating the same area on a large number of OLED substrates 100. Alternately, deposition chamber 140 can include a chamber face 195 that can be sealed to the body of deposition chamber 140, or removed and replaced, permitting a single deposition chamber 140 to be used to encapsulate a wide variety of OLED substrates of various sizes, shapes, and arrangements of OLED devices thereon.

Although the OLED substrate 100 and deposition chamber 140 are shown in a particular orientation, with substrate 100 above deposition chamber 140, other orientations can also be used. These include the opposite orientation where substrate 100 is below deposition chamber 140 or orientations where the substrate is held vertically or at an incline and engaged to the deposition chamber.

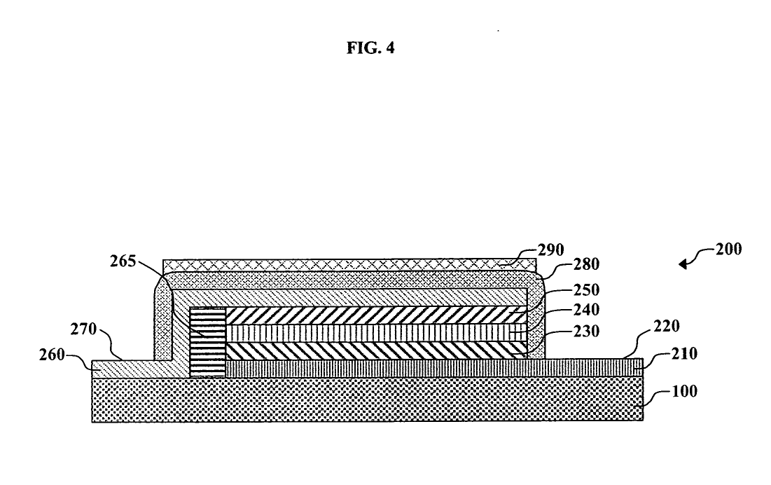

Turning now to FIG. 4, there is shown a schematic cross-sectional view of one embodiment of an OLED device that has been encapsulated by the method of the present invention. For clarity of illustration, electrode contacts are shown on opposite sides of the device; however, those skilled in the art will understand that electrode contacts can be on the same side or on adjacent sides. OLED device 200 is constructed on OLED substrate 100, and includes one or more anodes 210 with an area of anode contact 220, one or more cathodes 260 with an area of cathode contact 270, and a light-emitting layer 240. In OLED device 200, anode 210 is the bottom electrode and cathode 260 is the top electrode, but the practice of the present invention is not limited to this configuration. OLED device also commonly includes a hole-transporting layer 230 and an electron-transporting layer 250, and can also include other layers, e.g. electron-injecting layers, hole-injecting layers, and additional light-emitting layers, as is well known to those skilled in the art. Other features can also be included, e.g. insulator 265. Those skilled in the art will recognize that numerous other arrangements are possible, e.g. the use of a via to connect a top electrode with a substrate-level conductor. OLED device 200 shows only one emitting element. A pixelated display would comprise a plurality of such emitting elements within an emissive portion disposed over substrate 100 as described previously. Alternately, OLED devices having active matrix circuitry including transistors, such as thin-film-transistors (TFT), can also be used with the present invention. Active matrix circuitry includes multiple layers of conductive materials, semiconductive materials, and dielectric materials disposed between OLED substrate 100 and the lower electrode such as anode contact 220. Active matrix circuitry is often arranged so as the provide the electrical current to the lower electrode.

Encapsulation layer 280 is an example of a layer that can be formed by the method of the present invention. Encapsulation layer 280 can comprise organic, inorganic, or mixed organic and inorganic materials and can comprise a single layer or multiple layers of different materials or mixtures of materials. The use of an oxide layer that is highly conforming and that can be deposited at a temperature low enough for the OLED layers to survive is preferred. Encapsulation layer 280 can be deposited by atomic layer deposition, which provides a highly conformal film, and can comprise materials such as aluminum oxide, silicon dioxide, titanium dioxide, zirconium dioxide, magnesium oxide, hafnium dioxide, tantalum oxide, aluminum titanium oxide, and tantalum hafnium oxide. A low-temperature ALD deposition process (approximately 100-120° C.) provides an effective conformal coating of an oxide such as Al₂O₃. Encapsulation layer 280 can be used to provide protection against atmospheric contaminants, such as moisture and oxygen, where the encapsulation layer 280 is formed to enclose the OLED layers. That is, encapsulation layer 280 protects the sides of e.g. light-emitting layer 240 as well as the top. With substrate 100 on the bottom, encapsulation layer 280 provides a completely sealed environment for the organic layers (e.g. hole-transporting layer 230, light-emitting layer 240, and electron-transporting layer 250) in the emissive portion of OLED device 200. The thickness of the layer should be high enough to provide a moisture barrier, but low enough as to not induce high amounts of stress. If the light emission is to be viewed in the direction through the encapsulation, the thickness should also be low enough to ensure high light transmission. For example, Al₂O₃ layers are typically around 200 nm thick, but can range from 20 to 7,500 nm, and preferably from 100 to 400 nm. In the arrangement shown in FIG. 4, encapsulation layer 280 forms the primary moisture barrier layer, but in alternative embodiments encapsulation layer 280 can instead function as a seed layer, a smoothing layer, or a protection layer prior to formation of a second encapsulation layer that forms the primary moisture barrier layer. By using the method described herein, encapsulation layer 280 can be deposited onto the emissive portion of OLED device 200 as shown without depositing encapsulation layer 280 over the connector portion, which includes anode contact 220 and cathode contact 270.

A second encapsulation layer 290 can optionally be provided directly on encapsulation layer 280 for additional protection or as the primary moisture barrier layer. This second encapsulation layer 290 can comprise organic, inorganic, or mixed organic and inorganic materials and can comprise a single layer or multiple layers of different materials or mixtures of materials. For example, a layer deposited at or below room temperature and comprising highly chemically resistant polymer material can be used for additional protection. Second encapsulation layer 290 can be provided in the same deposition chamber as first encapsulation layer 280, or in a different deposition chamber. The second encapsulation can be a layer deposited by ALD or another method. Encapsulation layer 290 can cover the same area as encapsulation area 280, a larger area, or a smaller area. Encapsulation layer 290 can be used to provide surface protection to OLED device 200, against physical damage such as abrasion and chemical damage due to further processing reagents or to provide primary moisture and oxygen protection to OLED device 200. Encapsulation layer 290 can comprise a material that is resistant to physical damage, e.g. a parylene such as described for example in U.S. Patent Application Publication 2001/052752 A1. The chemical inertness and the ease of deposition of parylenes are well known. Furthermore, parylenes form highly conformal coatings that help in covering any stray particles and pinholes. Parylene coating is a room temperature deposition process that does not require any ultraviolet curing. The three standard parylenes are parylene N, parylene C, and parylene D

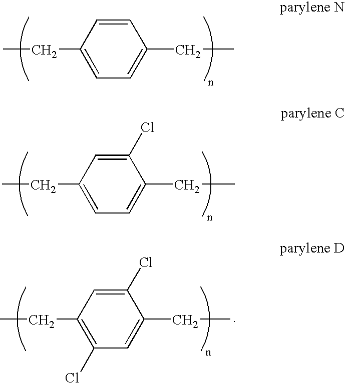

Although any parylene is suitable for the polymer layer of the devices of the present invention, parylene C is preferred because it is lowest of the three in oxygen permeability and moisture vapor transmission. Parylenes are deposited using standard techniques, starting from a dimeric form diparaxylylene (abbreviated DPX, DPX-C, and DPX-D for parylene N, parylene C, and parylene D, respectively). The dimer is evaporated and sent through a pyrolysis zone where the dimer's dibenzylic bonds homolyze to form highly reactive monomer species as illustrated below for parylene C

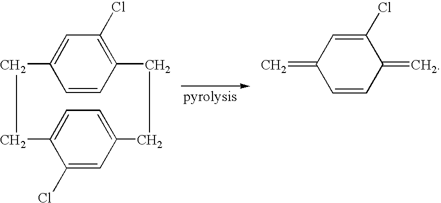

The monomers then travel to the deposition site, where they condense and polymerize on the device on contact. A well known adhesion promoter such as trichlorosilane or γ-methacryloxypropylenetrimethoxysilane can be vapor-deposited on the device prior to deposition of the parylene.

The present invention, however, is not limited to parylenes for the polymer layers. Any polymer with suitable properties can be used. In particular, suitable polymers are those that can be formed from vapor-phase monomer species that will condense and polymerize on a surface at a temperature below about 40° C., and preferably at room temperature (approximately 25° C.). For example, polymers laid down using plasma-enhanced polymer deposition techniques as disclosed in U.S. Patent Application Publication 2001/0052752 A1 and references therein.

OLED substrate 100 can either be light transmissive or opaque, depending on the intended direction of light emission. The light transmissive property is desirable for viewing the light emission through the substrate. Transparent glass or plastic are commonly employed in such cases. For applications where the light emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, ceramics, and circuit board materials, or any others commonly used in the formation of OLED devices, which can be either passive-matrix devices or active-matrix devices.

OLED device 200 can include layers commonly used for such devices. A bottom electrode is formed over OLED substrate 100 and is most commonly configured as an anode 210, although the practice of the present invention is not limited to this configuration. When light emission is viewed through the OLED substrate 100, anode 210 should be transparent or substantially transparent to the emission of interest. Common transparent anode materials useful in the present invention are indium-tin oxide and tin oxide, but other metal oxides can work including, but not limited to, aluminum- or indium-doped zinc oxide, magnesium-indium oxide, and nickel-tungsten oxide. In addition to these oxides, metal nitrides such as gallium nitride, metal selenides such as zinc selenide, and metal sulfides such as zinc sulfide, can be used as an anode material. For applications where light emission is viewed through the top electrode, the transmissive characteristics of the anode material are immaterial and any conductive material can be used, transparent, opaque or reflective. Example conductors for this application include, but are not limited to, gold, iridium, molybdenum, palladium, platinum, aluminum or silver. Desired anode materials can be deposited by any suitable way such as evaporation, sputtering, chemical vapor deposition, or electrochemical means. Anode materials can be patterned using well known photolithographic processes.

Although not always necessary, it is often useful that a hole-transporting layer 230 be formed and disposed over anode 210. Desired hole-transporting materials can be deposited by any suitable way such as evaporation, sputtering, chemical vapor deposition, electrochemical means, thermal transfer, or laser thermal transfer from a donor material. Hole-transporting materials useful in hole-transporting layer 230 are well known to include compounds such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. in U.S. Pat. No. 3,180,730. Other suitable triarylamines substituted with one or more vinyl radicals or at least one active hydrogen-containing group are disclosed by Brantley et al. in U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. Such compounds include those represented by structural Formula A 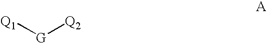
wherein:

Q₁ and Q₂ are independently selected aromatic tertiary amine moieties; and

G is a linking group such as an arylene, cycloalkylene, or alkylene group of a carbon to carbon bond.

In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural Formula A and containing two triarylamine moieties is represented by structural Formula B. 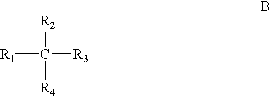
where:

R₁ and R₂ each independently represent a hydrogen atom, an aryl group, or an alkyl group or R₁ and R₂ together represent the atoms completing a cycloalkyl group; and

R₃ and R₄ each independently represent an aryl group, which is in turn substituted with a diaryl substituted amino group, as indicated by structural Formula C 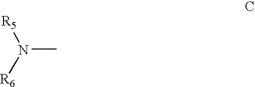
wherein R₅ and R₆ are independently selected aryl groups. In one embodiment, at least one of R₅ or R₆ contains a polycyclic fused ring structure, e.g., a naphthalene.

Another class of aromatic tertiary amines is the tetraaryldiamines. Desirable tetraaryldiamines include two diarylamino groups, such as indicated by Formula C, linked through an arylene group. Useful tetraaryldiamines include those represented by Formula D 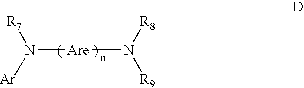
wherein:

each Are is an independently selected arylene group, such as a phenylene or anthracene moiety;

n is an integer of from 1 to 4; and

Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural Formulae A, B, C, D, can each in turn be substituted. Typical substituents include alkyl groups, alkoxy groups, aryl groups, aryloxy groups, and halogens such as fluoride, chloride, and bromide. The various alkyl and alkylene moieties typically contain from 1 to about 6 carbon atoms. The cycloalkyl moieties can contain from 3 to about 10 carbon atoms, but typically contain five, six, or seven carbon atoms, e.g. cyclopentyl, cyclohexyl, and cycloheptyl ring structures. The aryl and arylene moieties are typically phenyl and phenylene moieties.

The hole-transporting layer in an OLED device can be formed of a single or a mixture of aromatic tertiary amine compounds. Specifically, a triarylamine can be used, such as a triarylamine satisfying the Formula B, in combination with a tetraaryldiamine, such as indicated by Formula D. When a triarylamine is employed in combination with a tetraaryldiamine, the latter is positioned as a layer interposed between the triarylamine and the electron-injecting and transporting layer. The device and method described herein can be used to deposit single- or multi-component layers, and can be used to sequentially deposit multiple layers.

Another class of useful hole-transporting materials includes polycyclic aromatic compounds as described in EP 1 009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-emitting layer 240 produces light in response to hole-electron recombination. Light-emitting layer 240 is commonly disposed over hole-transporting layer 230. Desired organic light-emitting materials can be deposited by any suitable way such as evaporation, sputtering, chemical vapor deposition, electrochemical means, or radiation thermal transfer from a donor material. Useful organic light-emitting materials are well known. As more fully described in U.S. Pat. Nos. 4,769,292 and 5,935,721, the light-emitting layers of the OLED element comprise a luminescent or fluorescent material where electroluminescence is produced as a result of electron-hole pair recombination in this region. The light-emitting layers can be comprised of a single material, but more commonly include a host material doped with a guest compound or dopant where light emission comes primarily from the dopant. The dopant is selected to produce color light having a particular spectrum. The host materials in the light-emitting layers can be an electron-transporting material, as defined below, a hole-transporting material, as defined above, or another material that supports hole-electron recombination. The dopant is typically chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material. The device and method described herein can be used to coat multi-component guest/host layers without the need for multiple vaporization sources.

Host and emitting molecules known to be of use include, but are not limited to, those disclosed in U.S. Pat. Nos. 4,768,292, 5,141,671, 5,150,006, 5,151,629, 5,294,870, 5,405,709, 5,484,922, 5,593,788, 5,645,948, 5,683,823, 5,755,999, 5,928,802, 5,935,720, 5,935,721, and 6,020,078.

Metal complexes of 8-hydroxyquinoline and similar derivatives (Formula E) constitute one class of useful host materials capable of supporting electroluminescence, and are particularly suitable for light emission of wavelengths longer than 500 nm, e.g., green, yellow, orange, and red 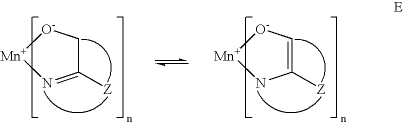
wherein:

M represents a metal;

n is an integer of from 1 to 3; and

Z independently in each occurrence represents the atoms completing a nucleus having at least two fused aromatic rings.

From the foregoing it is apparent that the metal can be a monovalent, divalent, or trivalent metal. The metal can, for example, be an alkali metal, such as lithium, sodium, or potassium; an alkaline earth metal, such as magnesium or calcium; or an earth metal, such as boron or aluminum. Generally, any monovalent, divalent, or trivalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is typically maintained at 18 or less.

The host material in light-emitting layer 240 can be an anthracene derivative having hydrocarbon or substituted hydrocarbon substituents at the 9 and 10 positions. For example, derivatives of 9,10-di-(2-naphthyl)anthracene constitute one class of useful host materials capable of supporting electroluminescence, and are particularly suitable for light emission of wavelengths longer than 400 nm, e.g. blue, green, yellow, orange or red.

Benzazole derivatives constitute another class of useful host materials capable of supporting electroluminescence, and are particularly suitable for light emission of wavelengths longer than 400 nm, e.g., blue, green, yellow, orange or red. An example of a useful benzazole is 2,2′,2″-(1,3,5-phenylene)-tris[1-phenyl-1H-benzimidazole].

Desirable fluorescent dopants include perylene or derivatives of perylene, derivatives of anthracene, tetracene, xanthene, rubrene, coumarin, rhodamine, quinacridone, dicyanomethylenepyran compounds, thiopyran compounds, polymethine compounds, pyrilium and thiapyrilium compounds, derivatives of distryrylbenzene or distyrylbiphenyl, bis(azinyl)methane boron complex compounds, and carbostyryl compounds.

Other organic emissive materials can be polymeric substances, e.g. polyphenylenevinylene derivatives, dialkoxy-polyphenylenevinylenes, poly-para-phenylene derivatives, and polyfluorene derivatives, as taught by Wolk et al. in commonly assigned U.S. Pat. No. 6,194,119 and references cited therein.

Although not always necessary, it is often useful that OLED device 200 includes an electron-transporting layer 250 disposed over light-emitting layer 240. Desired electron-transporting materials can be deposited by any suitable way such as evaporation, sputtering, chemical vapor deposition, electrochemical means, thermal transfer, or laser thermal transfer from a donor material. Preferred electron-transporting materials for use in electron-transporting layer 250 are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural Formula E, previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural Formula G are also useful electron-transporting materials. Other electron-transporting materials can be polymeric substances, e.g. polyphenylenevinylene derivatives, poly-para-phenylene derivatives, polyfluorene derivatives, polythiophenes, polyacetylenes, and other conductive polymeric organic materials known in the art.

A top electrode most commonly configured as cathode 260 is formed over the electron-transporting layer 250 or over light-emitting layer 240 if an electron-transporting layer is not used. When light emission is through the anode 210, the cathode material can be comprised of nearly any conductive material. Desirable materials have effective film-forming properties to ensure effective contact with the underlying organic layer, promote electron injection at low voltage, and have effective stability. Useful cathode materials often contain a low work function metal (<3.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprised of a thin layer of a low work function metal or metal salt capped with a thicker layer of conductive metal. One such cathode is comprised of a thin layer of LiF followed by a thicker layer of Al as described in U.S. Pat. No. 5,677,572. Other useful cathode materials include, but are not limited to, those disclosed in U.S. Pat. Nos. 5,059,861, 5,059,862, and 6,140,763.

When light emission is viewed through cathode 260, it should be transparent or nearly transparent. For such applications, metals should be thin or one should use transparent conductive oxides, or includes these materials. Optically transparent cathodes have been described in more detail in U.S. Pat. No. 5,776,623. Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

OLED device 200 can include other layers as well. For example, a hole-injecting layer can be formed over anode 210, as described in U.S. Pat. Nos. 4,720,432,6,208,075, EP 0 891 121 A1, and EP 1 029 909 A1. An electron-injecting layer, such as alkaline or alkaline earth metals, alkali halide salts, or alkaline or alkaline earth metal doped organic layers, can also be present between the cathode and the electron-transporting layer.

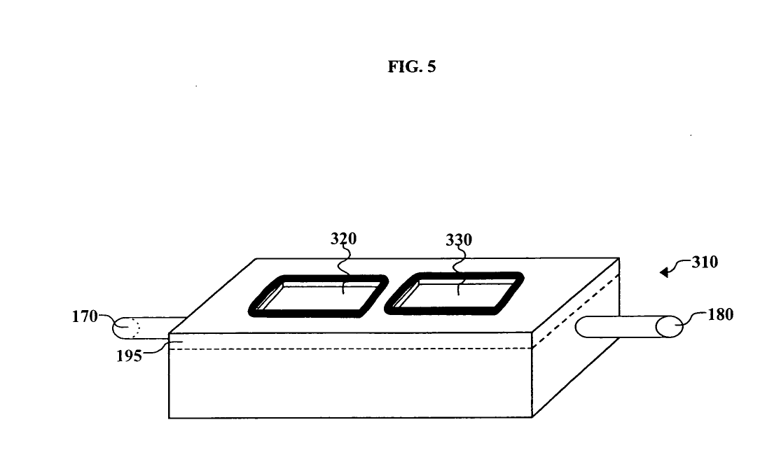

Turning now to FIG. 5, there is shown a three-dimensional view of another embodiment of an apparatus that can be used in the method of the present invention to encapsulate the emissive portion of one or more OLED devices. Deposition chamber 310 has a plurality of openings, e.g. openings 320 and 330. Deposition chamber 310 can be used to provide encapsulation layers over a plurality of areas on an OLED substrate with a plurality of OLED devices, with each opening 320 and 330 corresponding to one or more OLED devices.

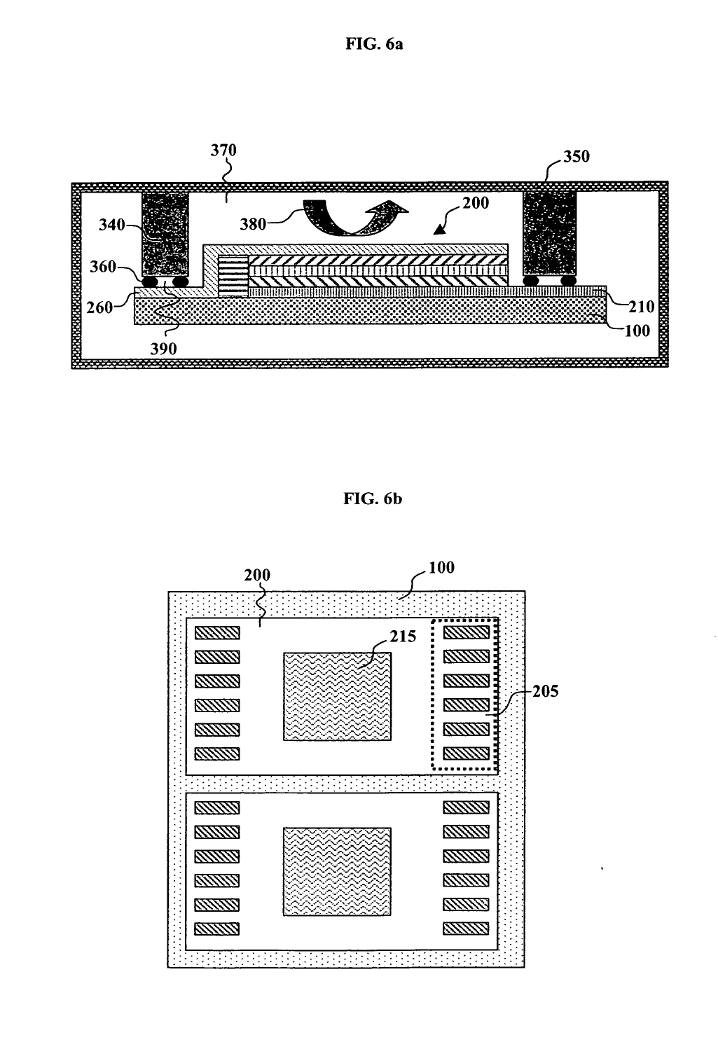

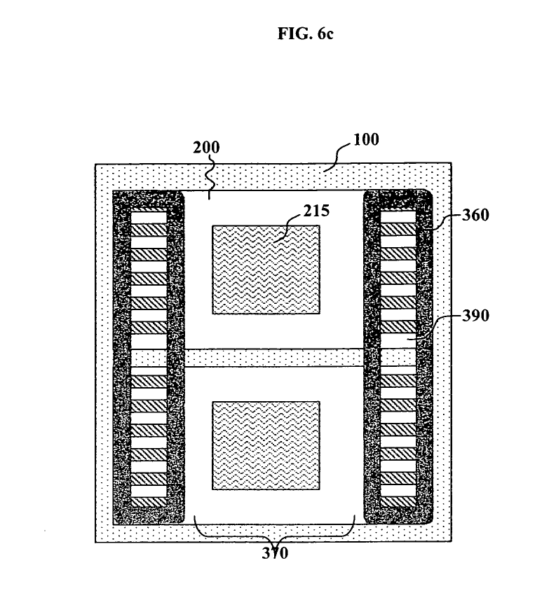

Turning now to FIG. 6A, there is shown a schematic cross-sectional view of another embodiment of an apparatus that can be used to encapsulate the emissive portion of one or more OLED devices. In this arrangement, OLED device 200 is completely enclosed in deposition chamber 350, which is a chamber for atomic layer deposition. A non-deposition environment is produced by sealing the connector portion of OLED device 200 from the overall deposition environment, e.g. by providing pressure from posts 340 against sealing material 360, which can be one or more O-rings, to define non-deposition environment 390 and a deposition environment, e.g. opening 370 defined by positioning OLED substrate 100 in sealing engagement as shown with opening 370. Subsequent atomic layer deposition of an encapsulation layer can be provided by gas flow 380 over the emissive portion of OLED device 200, although the connector portion will be protected from deposition of the encapsulation layer.

Turning now to FIG. 6B, there is shown a top view of OLED device 200 from FIG. 6A. OLED device 200 includes one or more connector portions 205, which can include anode contacts 220 and cathode contacts 270 as shown in FIG. 6A, and one or more emissive portions 215. Turning now to FIG. 6C, there is shown the same view showing how sealing material 360 defines a non-deposition environment 390 over the connector portion(s), and opening 370, which is a deposition environment, over emissive portion(s) 215.

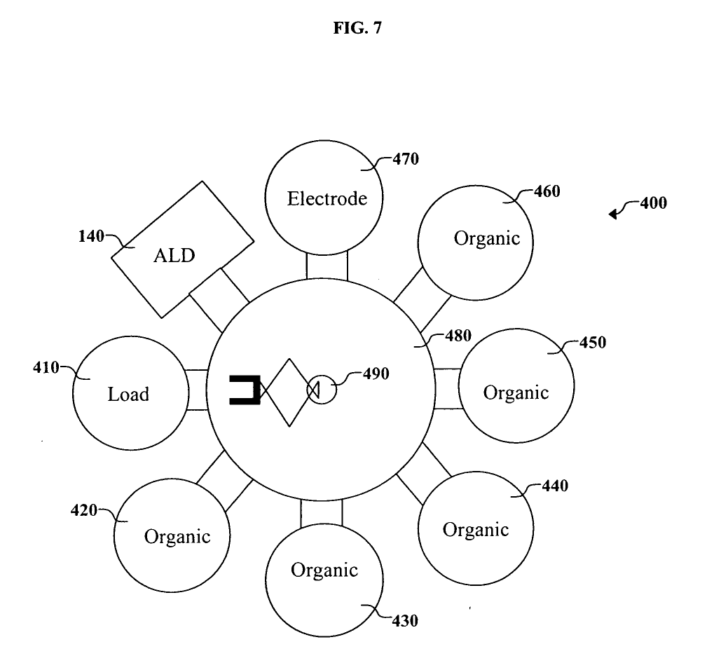

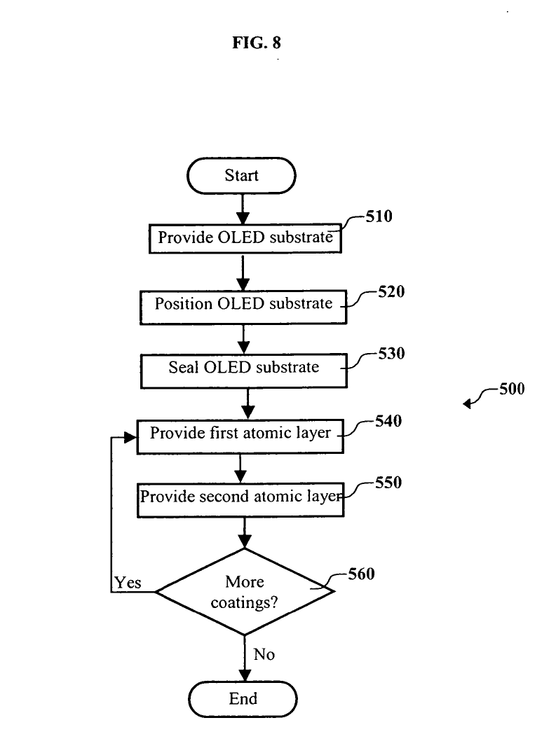

Turning now to FIG. 7, there is shown a schematic representation of a manufacturing tool for producing OLED devices according to an embodiment of the present invention. A manufacturing tool 400 incorporating an atomic layer deposition system according to one embodiment of the present invention is shown. This tool is configured to receive OLED substrates by way of a load chamber 410. Load chamber 410 removes oxygen or moisture by a vacuum pumping means (not shown) known in the art. The environment is maintained at a reduced pressure or replaced with an inert environment. The OLED substrate is then moved from load chamber 410 into a transfer chamber 480 by a substrate movement apparatus 490. Substrate movement apparatus 490 can for example be a robotic arm. The OLED substrate is then moved into one or more organic deposition chambers such as organic deposition chamber 420, organic deposition chamber 430, organic deposition chamber 440, organic deposition chamber 450, and organic deposition chamber 460 where the multiple organic layers are deposited. Following deposition of the organic layers, the OLED substrate is moved into electrode deposition chamber 470 for deposition of a metal layer. The OLED substrate is then positioned in sealing engagement with deposition chamber 140 and the emissive portion of the OLED substrate is encapsulated as described herein. The OLED substrate is then removed by way of load chamber 410 or a similar additional chamber (not shown). This configuration whereby each process chamber is connected by one or more transfer chambers is referred to as a cluster manufacturing tool configuration. Alternately, each chamber for subsequent process steps can be arranged to connect to one another so that the substrate is passed directionally from one chamber to the next in the desired order of the process steps without the need for a transfer chamber. Such an alternate configuration is referred to as an in-line manufacturing tool configuration. In order for each chamber to operate at different pressures, each chamber can be separated from transfer chamber 480 or from other connected chambers by a gate valve that opens during substrate transfers and can be closed during processing.

Turning now to FIG. 8, and referring also to FIG. 3, there is shown a block diagram of one embodiment of the method of the present invention. At the start of process 500, an OLED substrate 100 having one or more OLED devices, each device having an emissive portion and a connector portion as described herein, is provided (Step 510). The OLED substrate 100 is positioned in a sealing engagement with the opening 150 of the deposition chamber 140 by positioning the OLED substrate 100 against the opening 150 (Step 520) and applying pressure, e.g. by mechanical pressure against the OLED substrate 100 or by a pressure difference between the interior and the exterior of the deposition chamber 140 (Step 530). The next steps deposit an encapsulation layer onto the emissive portion of OLED substrate 100 by atomic layer deposition (ALD). ALD is accomplished by providing for alternating reactive atomic layers. A first atomic layer is provided (Step 540) by e.g. providing via gas inlet 170 a pulse of a vaporized trialkyl aluminum compound to react with free hydroxyl groups on the OLED device. A second atomic layer is provided (Step 550) by e.g. providing via gas inlet 170 a pulse of a vapor that will react with the layer of aluminum alkyl groups, such as water vapor or ozone, to provide in this example an aluminum oxide layer. Steps 540 and 550 are repeated, each repetition providing an additional atomic layer, until a sufficient thickness of the encapsulation layer is provided. The process can also include a purge of the deposition environment after each step. When the thickness of the layer is sufficient (Step 560), the process is ended.

The invention has been described in detail with particular reference to certain preferred embodiments thereof, but it will be understood that variations and modifications can be effected within the spirit and scope of the invention.

### PARTS LIST

100 OLED substrate
110 OLED device
115 row drivers
120 emissive portion
125 column drivers
130 connector portion
135 connector pad
140 deposition chamber
150 opening
160 sealing material
170 gas inlet
175 sealing engagement
180 outlet
190 heater
195 chamber face
200 OLED device
205 connector portion
210 anode
215 emissive portion
220 anode contact
230 hole-transporting layer
240 light-emitting layer
250 electron-transporting layer
260 cathode
265 insulator
270 cathode contact
280 encapsulation layer
290 encapsulation layer
310 deposition chamber
320 opening
330 opening
340 post
350 deposition chamber
360 sealing material
370 opening
380 gas flow
390 non-deposition environment
400 manufacturing tool
410 load chamber
420 organic deposition chamber
430 organic deposition chamber
440 organic deposition chamber
450 organic deposition chamber
460 organic deposition chamber
470 electrode deposition chamber
480 transfer chamber
490 substrate movement apparatus
500 process
510 block
520 block
530 block
540 block
550 block
560 decision block

1. A method of providing an encapsulation layer over an emissive portion of an OLED device comprising:
a) providing an OLED substrate having one or more OLED devices, each device having an emissive portion and a connector portion;
b) positioning the OLED substrate in sealing engagement with at least one opening in a deposition chamber to define a deposition environment for the emissive portion(s) and a non-deposition environment for the connector portion(s); and
c) depositing in the deposition environment an encapsulation layer onto the emissive portion of the OLED device through the opening without depositing the encapsulation layer over the connector portion.

2. The method according to claim 1 wherein the deposition environment is at a lower pressure than the non-deposition environment.

3. The method according to claim 1 further including providing a second encapsulation layer directly on the encapsulation layer.

4. The method according to claim 3 wherein the second encapsulation layer includes a parylene.

5. The method according to claim 1 wherein the sealing engagement is provided by a sealing material on the deposition chamber, the OLED substrate, or both.

6. The method according to claim 5 wherein the sealing material is an O-ring.

7. The method according to claim 5 wherein the deposition environment is at a lower pressure than the non-deposition environment.

8. The method according to claim 7 wherein an inert gas is provided in the non-deposition environment.

9. The method according to claim 1 wherein the encapsulation layer is deposited by atomic layer deposition.

10. The method according to claim 9 wherein the encapsulation layer includes aluminum oxide, silicon dioxide, titanium dioxide, zirconium dioxide, magnesium oxide, hafnium dioxide, tantalum oxide, aluminum titanium oxide, or tantalum hafnium oxide.

11. The method according to claim 9 further including providing a second encapsulation layer directly on the encapsulation layer.

12. The method according to claim 1 wherein the OLED substrate has a plurality of OLED devices and there are a plurality of openings in the deposition chamber, with each opening corresponding to one or more OLED devices.

13. The method according to claim 1 wherein the OLED substrate has a plurality of OLED devices and there is a single opening in the deposition chamber.

14. A method of providing an encapsulation layer over an emissive portion of an OLED device comprising:
a) providing an OLED substrate having one or more OLED devices, each device having an emissive portion and a connector portion;
b) positioning the OLED substrate in sealing engagement with at least one opening in a deposition chamber to define a deposition environment for the emissive portion(s) and a non-deposition environment for the connector portion(s); and
c) depositing by atomic layer deposition an encapsulation layer onto the emissive portion of the OLED device through the opening without depositing the encapsulation layer over the connector portion.

15. The method according to claim 14 wherein the deposition environment is at a lower pressure than the non-deposition environment.

16. The method according to claim 14 further including providing a second encapsulation layer directly on the encapsulation layer.

17. The method according to claim 16 wherein the second encapsulation layer includes a parylene.

18. The method according to claim 14 wherein the sealing engagement is provided by a sealing material on the deposition chamber, the OLED substrate, or both.

19. The method according to claim 18 wherein the sealing material is an O-ring.

20. The method according to claim 18 wherein the deposition environment is at a lower pressure than the non-deposition environment.

21. The method according to claim 20 wherein an inert gas is provided in the non-deposition environment.

22. The method according to claim 14 wherein the encapsulation layer includes aluminum oxide, silicon dioxide, titanium dioxide, zirconium dioxide, magnesium oxide, hafnium dioxide, tantalum oxide, aluminum titanium oxide, or tantalum hafnium oxide.

23. The method according to claim 14 wherein the OLED substrate has a plurality of OLED devices and there are a plurality of openings in the deposition chamber, with each opening corresponding to one or more OLED devices.

24. The method according to claim 14 wherein the OLED substrate has a plurality of OLED devices and there is a single opening in the deposition chamber.
